(19) United States
(12) Patent Application Publication
(10) Pub. No.: US 2025/0081675 A1
(43) Pub. Date: Mar. 6, 2025

(54) LIGHT-EMITTING DEVICE AND ELECTRONIC APPARATUS

(71) Applicant: SEIKO EPSON CORPORATION, Tokyo (JP)

(72) Inventor: Shinji TERAO, FUJIMI-MACHI (JP)

(73) Assignee: SEIKO EPSON CORPORATION, Tokyo (JP)

(21) Appl. No.: 18/818,634

(22) Filed: Aug. 29, 2024

(30) Foreign Application Priority Data
Aug. 31, 2023 (JP) 2023-141301

(51) Int. Cl. H01L 33/22; H01L 25/075; H01L 33/00; H01L 33/24; H01L 33/44; H01L 33/58; H01L 33/60; H01L 33/62

(52) U.S. Cl. CPC H10H 20/82; H01L 25/0753; H10H 20/018; H10H 20/821; H10H 20/84; H10H 20/855; H10H 20/856; H10H 20/857; H10H 20/882

(57) ABSTRACT

A light-emitting device including a substrate; a first stacked body including a first semiconductor layer, a second semiconductor layer, and a first light-emitting layer provided between the first semiconductor layer and the second semiconductor layer; a first electrode provided between the substrate and the first stacked body, and electrically coupled to the first semiconductor layer; a second electrode provided on a side of the first stacked body opposite to the substrate, having a light-transmitting property, including a first facing surface facing the substrate, and electrically coupled to the second semiconductor layer; a first insulating layer including a first portion provided at a side surface of the first stacked body, and a second portion provided at the first facing surface, and extending from the first portion along the first facing surface; and a first metal layer provided over the first portion and the second portion.

The present application is based on, and claims priority from JP Application Serial Number 2023-141301, filed Aug. 31, 2023, the disclosure of which is hereby incorporated by reference herein in its entirety.

### BACKGROUND

### 1. Technical Field

The present disclosure relates to a light-emitting device and an electronic apparatus.

### 2. Related Art

A light-emitting element such as a light emitting diode (LED) is applied to a light source of a display device and the like.

For example, WO 2019/038961 describes a micro LED element including a nitride semiconductor layer in which an N-type layer, a light-emitting layer, and a P-type layer are stacked in this order as viewed from a light emission surface side, a P-side electrode layer formed at the P-type layer, and an N-side electrode layer stacked at the light emission surface.

Improvement in light extraction efficiency of the micro LED element as described above has been desired.

### SUMMARY

An aspect of a light-emitting device according to the present disclosure includes
a substrate,
a first stacked body including a first semiconductor layer of a first conductivity type, a second semiconductor layer of a second conductivity type different from the first conductivity type, and a first light-emitting layer provided between the first semiconductor layer and the second semiconductor layer,
a first electrode provided between the substrate and the first stacked body, and electrically coupled to the first semiconductor layer,
a second electrode provided on a side of the first stacked body opposite to the substrate, having a light-transmitting property, including a first facing surface facing the substrate, and electrically coupled to the second semiconductor layer,
a first insulating layer including a first portion provided at a side surface of the first stacked body, and a second portion provided at the first facing surface, and extending from the first portion along the first facing surface, and
a first metal layer provided over the first portion and the second portion.

An aspect of an electronic apparatus according to the present disclosure includes an aspect of the light-emitting device.

### BRIEF DESCRIPTION OF THE DRAWINGS

FIG. 1 is a cross-sectional view schematically illustrating a light-emitting device according to the present embodiment.

FIG. 2 is a cross-sectional view schematically illustrating the light-emitting device according to the present embodiment.

FIG. 3 is a cross-sectional view schematically illustrating a manufacturing step of the light-emitting device according to the present embodiment.

FIG. 4 is a cross-sectional view schematically illustrating a manufacturing step of the light-emitting device according to the present embodiment.

FIG. 5 is a cross-sectional view schematically illustrating a manufacturing step of the light-emitting device according to the present embodiment.

FIG. 6 is a cross-sectional view schematically illustrating a manufacturing step of the light-emitting device according to the present embodiment.

FIG. 7 is a cross-sectional view schematically illustrating a manufacturing step of the light-emitting device according to the present embodiment.

FIG. 8 is a cross-sectional view schematically illustrating a manufacturing step of the light-emitting device according to the present embodiment.

FIG. 9 is a cross-sectional view schematically illustrating a manufacturing step of the light-emitting device according to the present embodiment.

FIG. 10 is a cross-sectional view schematically illustrating a manufacturing step of the light-emitting device according to the present embodiment.

FIG. 11 is a diagram schematically illustrating a projector according to the present embodiment.

FIG. 12 is a plan view schematically illustrating a display according to the present embodiment.

FIG. 13 is a cross-sectional view schematically illustrating the display according to the present embodiment.

FIG. 14 is a perspective view schematically illustrating a head-mounted display according to the present embodiment.

FIG. 15 is a diagram schematically illustrating an image forming device and a light-guiding device of the head-mounted display according to the present embodiment.

### DESCRIPTION OF EMBODIMENTS

A preferred embodiment of the present disclosure is described in detail below with reference to the drawings. Note that the embodiment described below do not unduly limit the content of the present disclosure described in the claims. In addition, not all the configurations described below are essential constituent elements of the present disclosure.

### 1. Light-Emitting Device

### 1.1. Configuration

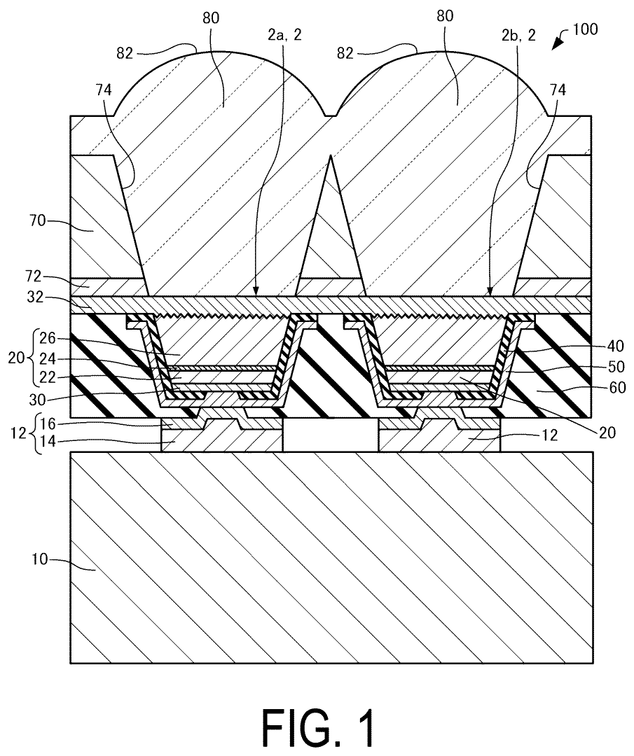

First, a light-emitting device according to the present embodiment is described with reference to the drawings. FIG. 1 is a perspective view schematically illustrating a light-emitting device 100 according to the present embodiment.

As illustrated in FIG. 1, the light-emitting device 100 includes, for example, a substrate 10, a stacked body 20, a p-electrode 30, an n-electrode 32, an insulating layer 40, a lower metal layer 50, a protective layer 60, an upper metal layer 70, and a light-transmissive member 80. The stacked body 20, the p-electrode 30, the n-electrode 32, the insulating layer 40, and the lower metal layer 50 constitute a light-emitting element 2. The light-emitting element 2 is an LED, for example.

The substrate 10 is, for example, a silicon substrate. The substrate 10 is provided with a pad 12. For example, the pad 12 includes a first layer 14 and a second layer 16. The first layer 14 is provided at the substrate 10. For the first layer 14, for example, a layer in which a Ti layer and a Pt layer are stacked in this order from the substrate 10 side is used. The second layer 16 is provided at the first layer 14. The second layer 16 is, for example, an Au layer.

The substrate 10 may be provided with a driving circuit for driving the light-emitting element 2. The light-emitting element 2 is mounted at the substrate 10 via the pad 12. The light-emitting element 2 is junction-down mounted, for example. For example, a plurality of the light-emitting elements 2 are provided. As viewed in a direction in which a p-type semiconductor layer 22 and a light-emitting layer 24 of the stacked body 20 are stacked (hereinafter, may be simply referred to as a “stacking direction”), the plurality of light-emitting elements 2 may be arrayed in a matrix. In the illustrated example, a first light-emitting element 2a and a second light-emitting element 2b are provided as the light-emitting elements 2. A plurality of the pads 12 are provided so as to correspond to the plurality of light-emitting elements 2.

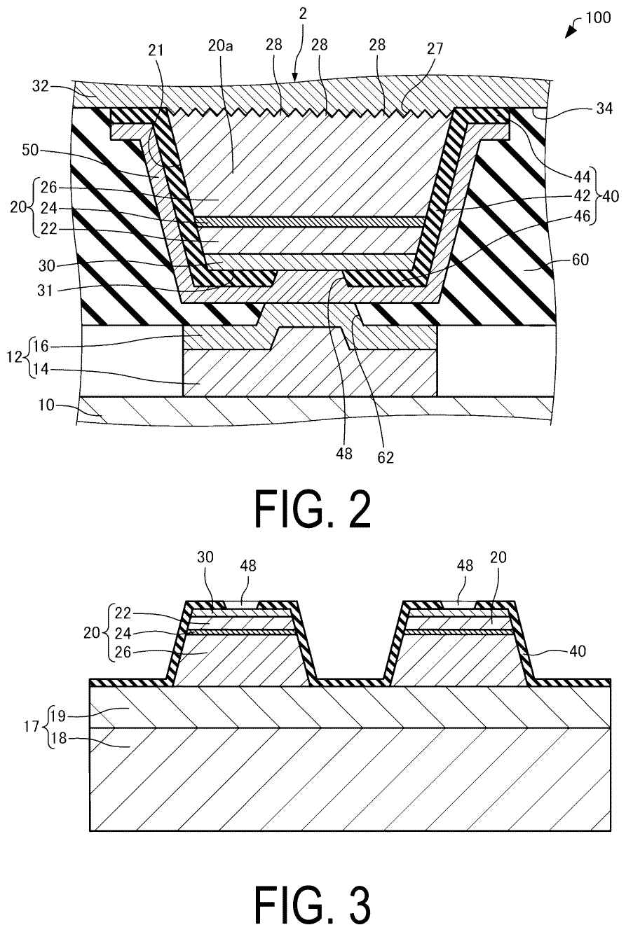

The stacked body 20 is provided between the p-electrode 30 and the n-electrode 32. Here, FIG. 2 is an enlarged view of FIG. 1 illustrating a vicinity of the stacked body 20. As illustrated in FIG. 2, the stacked body 20 includes a tapered portion 20a having a tapered shape in which a width becomes wider as viewed from the p-electrode 30 side toward the n-electrode 32 side. The width of the tapered portion 20a gradually increases as viewed from the p-electrode 30 side toward the n-electrode 32 side. In the illustrated example, the tapered portion 20a has a trapezoidal shape. Note that a width is a size in a direction orthogonal to the stacking direction. A side surface 21 of the tapered portion 20a is inclined with respect to the stacking direction. The side surface 21 of the tapered portion 20a constitutes a side surface of the stacked body 20.

The stacked body 20 includes the p-type semiconductor layer 22, the light-emitting layer 24, and an n-type semiconductor layer 26. The p-type semiconductor layer 22, the light-emitting layer 24, and the n-type semiconductor layer 26 constitute the tapered portion 20a. Each of the p-type semiconductor layer 22, the light-emitting layer 24, and the n-type semiconductor layer 26 is, for example, a Group III nitride semiconductor, and has a wurtzite crystal structure.

The p-type semiconductor layer 22 is provided at the p-electrode 30. The p-type semiconductor layer 22 is provided between the p-electrode 30 and the light-emitting layer 24. The p-type semiconductor layer 22 has a first conductivity type. The p-type semiconductor layer 22 is, for example, a p-type GaN layer doped with Mg.

The light-emitting layer 24 is provided at the p-type semiconductor layer 22. The light-emitting layer 24 is provided between the p-type semiconductor layer 22 and the n-type semiconductor layer 26. The light-emitting layer 24 has an i-type conductivity type in which impurities are not intentionally doped. The light-emitting layer 24 generates light when a current is injected thereinto. The light-emitting layer 24 includes, for example, a well layer and a barrier layer. The well layer and the barrier layer are i-type semiconductor layers. The well layer is, for example, an InGaN layer. The barrier layer is, for example, a GaN layer. The light-emitting layer 24 has a multiple quantum well (MQW) structure constituted by the well layer and the barrier layer.

The number of well layers and the number of barrier layers constituting the light-emitting layer 24 are not particularly limited. For example, only one well layer may be provided, and in this case, the light-emitting layer 24 has a single quantum well (SQW) structure.

The n-type semiconductor layer 26 is provided at the light-emitting layer 24. The n-type semiconductor layer 26 is provided between the light-emitting layer 24 and the n-electrode 32. In the illustrated example, a size of the n-type semiconductor layer 26 in the stacking direction is larger than a size of the p-type semiconductor layer 22 in the stacking direction. The n-type semiconductor layer 26 has a second conductivity type different from the first conductivity type. The n-type semiconductor layer 26 is, for example, an n-type GaN layer doped with Si.

The n-type semiconductor layer 26 includes a contact surface 27 in contact with the n-electrode 32. The contact surface 27 is provided with a plurality of protrusions 28. The plurality of protrusions 28 are provided, for example, periodically. A height of the protrusion 28 is, for example, equal to or greater than 400 nm. A distance D between distal ends of adjacent ones of the protrusions 28 is 230 nm or less for example. The plurality of protrusions 28 may form a moth-eye structure. In the illustrated example, the stacked body 20 includes the tapered portion 20a, and the plurality of protrusions 28. The plurality of protrusions 28 can achieve a smooth change in refractive index at an interface between the n-type semiconductor layer 26 and the n-electrode 32 in a direction from the n-type semiconductor layer 26 toward the n-electrode 32. Thus, light reflected by the interface between the n-type semiconductor layer 26 and the n-electrode 32 can be reduced. Note that although not illustrated in the drawing, the plurality of protrusions 28 may be randomly provided.

In the light-emitting device 100, a pin diode is configured by the p-type semiconductor layer 22, the i-type light-emitting layer 24, and the n-type semiconductor layer 26. In the light-emitting device 100, when a forward bias voltage of the pin diode is applied between the p-electrode 30 and the n-electrode 32, an electric current is injected into the light-emitting layer 24 to cause recombination of electrons and holes in the light-emitting layer 24. The light-emitting layer 24 generates light by the recombination.

The p-electrode 30 is provided between the substrate 10 and the p-type semiconductor layer 22. The p-electrode 30 is electrically coupled to the p-type semiconductor layer 22. The p-type semiconductor layer 22 may be in ohmic contact with the p-electrode 30. As the n-electrode 30, an electrode formed by stacking a Pd layer, a Pt layer, and an Au layer in this order from the p-type semiconductor layer 22 side, for example. The p-electrode 30 reflects the light generated in the light-emitting layer 24 toward the n-electrode 32 side.

The p-electrode 30 is an electrode on one side for injecting an electric current into the light-emitting layer 24. For example, a potential of a data signal is applied to the p-electrode 30. In the plurality of light-emitting elements 2, the p-electrodes 30 are spaced apart from each other.

The n-electrode 32 is provided on a side of the stacked body 20 opposite to the substrate 10. The n-electrode 32 is provided at the n-type semiconductor layer 26. The n-electrode 32 is provided between the n-type semiconductor layer 26 and the light-transmissive member 80. The n-electrode 32 is disposed to face the substrate 10. The n-electrode 32 includes a facing surface 34 facing the substrate 10. In the illustrated example, the facing surface 34 is a lower surface of the n-electrode 32. The n-electrode 32 is electrically coupled to the n-type semiconductor layer 26. The n-type semiconductor layer 26 may be in ohmic contact with the n-electrode 32. The n-electrode 32 has a light-transmitting property. Specifically, the n-electrode 32 transmits the light generated in the light-emitting layer 24. The light generated in the light-emitting layer 24 is emitted from the n-electrode 32 side. A material of the n-electrode 32 is, for example, indium tin oxide (ITO).

The n-electrode 32 is an electrode on another side for injecting the electric current into the light-emitting layer 24. For example, a constant potential is applied to the n-electrode 32. A ground potential may be applied to the n-electrode 32. In the plurality of light-emitting elements 2, the n-electrode 32 is, for example, a common electrode. In the example illustrated in FIG. 1, the n-electrode 32 of the first light-emitting element 2a, and the n-electrode 32 of the second light-emitting element 2b are continuously and integrally provided.

The insulating layer 40 is provided to cover the stacked body 20. The insulating layer 40 surrounds the stacked body 20, as viewed in the stacking direction, for example. The insulating layer 40 has a light-transmitting property. Specifically, the insulating layer 40 transmits the light generated in the light-emitting layer 24. The insulating layer 40 is a SiO₂ layer, for example. As illustrated in FIG. 2, the insulating layer 40 includes, for example, a first extending portion 42, a second extending portion 44, and a third extending portion 46.

The first extending portion 42 of the insulating layer 40 is provided at the side surface 21 of the stacked body 20. The first extending portion 42 extends along the side surface 21. The first extending portion 42 covers an entirety of the side surface 21, for example.

The second extending portion 44 of the insulating layer 40 is provided at the facing surface 34 of the n-electrode 32. In the illustrated example, the second extending portion 44 is provided at a portion of the facing surface 34 parallel to an upper surface of the substrate 10. The second extending portion 44 is coupled to the first extending portion 42. The second extending portion 44 extends from the first extending portion 42 along the facing surface 34.

The third extending portion 46 of the insulating layer 40 is provided at a lower surface 31 of the p-electrode 30. The third extending portion 46 is coupled to the first extending portion 42. The third extending portion 46 extends from the first extending portion 42 along the lower surface 31. A first contact hole 48 is formed at the third extending portion 46.

The lower metal layer 50 is provided over the first extending portion 42 and the second extending portion 44. In the illustrated example, the lower metal layer 50 is further provided over the third extending portion 46. The lower metal layer 50 is in contact with the extending portions 42, 44, and 46.

The lower metal layer 50 is further provided at the first contact hole 48. The lower metal layer 50 is coupled to the p-electrode 30. The lower metal layer 50 is further coupled to the pad 12. The lower metal layer 50 may be eutectic-bonded to the pad 12. The lower metal layer 50 may be Au—Au bonded to the pad 12. The pad 12 is electrically coupled to the p-electrode 30 via the lower metal layer 50. The lower metal layer 50 is, for example, an Au layer or an Al layer. The lower metal layer 50 reflects the light generated in the light-emitting layer 24 toward the stacked body 20 side.

As illustrated in FIG. 1, the protective layer 60 is provided to cover the light-emitting element 2. The protective layer 60 surrounds the stacked body 20 as viewed in the stacking direction. The protective layer 60 is provided between the first light-emitting element 2a and the second light-emitting element 2b. The protective layer 60 is provided between the substrate 10 and the p-electrode 30. In the illustrated example, the protective layer 60 is separated from the substrate 10 via an air gap. The protective layer 60 is a SiO₂ layer, for example. The protective layer 60 protects the light-emitting element 2 from foreign matter or the like, and prevents disconnection of the n-electrode 32 by being in contact with the n-electrode 32 between the light-emitting elements 2.

As illustrated in FIG. 2, a second contact hole 62 is formed at the protective layer 60. In the illustrated example, the second contact hole 62 is provided with the second layer 16 of the pad 12.

As illustrated in FIG. 1, the upper metal layer 70 is provided on a side of the n-electrode 32 opposite to the substrate 10. In the illustrated example, the upper metal layer 70 is provided above the n-electrode 32 via an adhesion layer 72. The adhesion layer 72 is, for example, a TiN layer. The adhesion layer 72 improves adhesion between the n-electrode 32 and the upper metal layer 70. For example, the upper metal layer 70 does not overlap the stacked body 20 as viewed in the stacking direction. The upper metal layer 70 is, for example, an Al layer.

The upper metal layer 70 includes a reflective surface 74. The reflective surface 74 is a side surface of the upper metal layer 70. In the illustrated example, the reflective surface 74 is located on an extension of the side surface 21 of the tapered portion 20a. An inclination of the reflective surface 74 with respect to the stacking direction is, for example, the same as an inclination of the side surface 21 with respect to the stacking direction. A plurality of the reflective surfaces 74 are provided so as to correspond to the plurality of light-emitting elements 2. The reflective surface 74 reflects the light generated in the light-emitting layer 24 toward the light-transmissive member 80 side.

The light-transmissive member 80 is provided on the side of the n-electrode 32 opposite to the substrate 10. The light-transmissive member 80 is provided at the n-electrode 32. The light-transmissive member 80 is in contact with the reflective surface 74 of the upper metal layer 70. The upper metal layer 70 surrounds, for example the light-transmissive member 80 as viewed in the stacking direction. A material of the light-transmissive member 80 is, for example, SiON. The light-transmissive member 80 transmits the light transmitted through the n-electrode 32. The light-transmissive member 80 transmits the light reflected by the reflective surface 74.

The light-transmissive member 80 includes an emission surface 82 that emits the light generated in the light-emitting layer 24. The emission surface 82 is a surface on a side of the light-transmissive member 80 opposite to the substrate 10. The emission surface 82 is, for example, a curved surface. In the illustrated example, the emission surface 82 is a convex surface. A plurality of the light-transmissive members 80 are provided so as to correspond to the plurality of light-emitting elements 2. In the illustrated example, the adjacent light-transmissive members 80 are provided continuously and integrally with each other. The plurality of light-transmissive members 80 form, for example, a microlens array.

### 1.2. Operations and Effects

In the light-emitting device 100, the first light-emitting element 2a includes the stacked body 20 as a first stacked body including the p-type semiconductor layer 22 as a first semiconductor layer, the n-type semiconductor layer 26 as a second semiconductor layer, and the light-emitting layer 24 as a first light-emitting layer. Further, the first light-emitting element 2a includes the p-electrode 30 as a first electrode provided between the substrate 10 and the stacked body 20, and electrically coupled to the p-type semiconductor layer 22. Further, the first light-emitting element 2a includes the n-electrode 32 as a second electrode provided on the side of the stacked body 20 opposite to the substrate 10, having a light-transmitting property, including the facing surface 34 as a first facing surface facing the substrate 10, and electrically coupled to the p-type semiconductor layer 22. Further, the first light-emitting element 2a includes the insulating layer 40 as a first insulating layer including the first extending portion 42 as a first portion provided at the side surface 21 of the stacked body 20, and the second extending portion 44 as a second portion provided at the facing surface 34, and extending from the first extending portion 42 along the facing surface 34. Further, the first light-emitting element 2a includes the lower metal layer 50 as a first metal layer provided over the first extending portion 42 and the second extending portion 44.

Therefore, in the light-emitting device 100, the light generated in the light-emitting layer 24 can be reflected more toward the stacked body 20 side, by the lower metal layer 50, as compared to a case where the lower metal layer is not provided over the first extending portion and the second extending portion of the insulating layer, and is provided only at a part of the first extending portion, for example. Accordingly, light extraction efficiency can be improved.

In the light-emitting device 100, the lower metal layer 50 is coupled to the p-electrode 30. Therefore, in the light-emitting device 100, for example, in contrast to a case where the lower metal layer is separated from the p-electrode, miniaturization can be achieved. When the lower metal layer and the p-electrode are separated from each other, it is necessary to consider misalignment between the lower metal layer and the p-electrode at the time of design, which makes it difficult to achieve miniaturization.

In the light-emitting device 100, the second light-emitting element 2b includes the stacked body 20 as a second stacked body including the p-type semiconductor layer 22 as a third semiconductor layer, the n-type semiconductor layer 26 as a fourth semiconductor layer, and the light-emitting layer 24 as a second light-emitting layer. Further, the second light-emitting element 2b includes the p-electrode 30 as a third electrode provided between the substrate 10 and the stacked body 20, and electrically coupled to the p-type semiconductor layer 22. Further, the second light-emitting element 2b includes the n-electrode 32 as a fourth light-transmissive electrode provided on the side of the stacked body 20 opposite to the substrate 10, including the facing surface 34 as a second facing surface facing the substrate 10, and electrically coupled to the p-type semiconductor layer 22. Further, the second light-emitting element 2b includes the insulating layer 40 as a second insulating layer including the first extending portion 42 as a third portion provided at the side surface 21 of the stacked body 20, and the second extending portion 44 as a fourth portion provided at the facing surface 34, and extending from the first extending portion 42 along the facing surface 34. Further, the second light-emitting element 2b includes the lower metal layer 50 as a second metal layer provided over the first extending portion 42 and the second extending portion 44. Therefore, in the light-emitting device 100, crosstalk between the first light-emitting element 2a and the second light-emitting element 2b can be reduced by the lower metal layer 50.

In the light-emitting device 100, the p-electrode 30 of the first light-emitting element 2a and the p-electrode 30 of the second light-emitting element 2b are continuously and integrally provided. Therefore, in the light-emitting device 100, the p-electrode 30 can be used as a common electrode in the first light-emitting element 2a and the second light-emitting element 2b.

In the light-emitting device 100, the stacked body 20 includes the tapered portion 20a having a width that becomes larger as viewed from the p-electrode 30 side toward the n-electrode 32 side. For this reason, in the light-emitting device 100, the light generated in the light-emitting layer 24 can be reflected toward the n-electrode 32 side at the side surface 21.

The light-emitting device 100 includes the upper metal layer 70 as a third metal layer provided on the side of the n-electrode 32 opposite to the substrate 10, and including the reflective surface 74 for reflecting the light generated in the light-emitting layer 24, and the reflective surface 74 is located on the extension of the side surface 21 of the tapered portion 20a. Therefore, in the light-emitting device 100, it is possible to emit light having a narrower radiation angle while suppressing leakage of the light transmitted through the n-electrode 32 to an outside.

The light-emitting device 100 includes the light-transmissive member 80 provided on the side of the n-electrode 32 opposite to the substrate 10 and in contact with the reflective surface 74. Therefore, in the light-emitting device 100, light transmitted through the light-transmissive member 80 and incident on the reflective surface 74 can be reflected more reliably toward the light-transmissive member 80 side at the reflective surface 74.

In the light-emitting device 100, the emission surface 82 on the side of the light-transmissive member 80 opposite to the substrate 10 is a curved surface. Therefore, in the light-emitting device 100, the light-transmissive member 80 can function as a lens.

In the light-emitting device 100, the insulating layer 40 has a light-transmitting property. In the light-emitting device 100, even when the light generated in the light-emitting layer 24 is transmitted through the light-transmissive insulating layer 40, the light transmitted through the insulating layer 40 can be reflected to the stacked body 20 side by the lower metal layer 50.

Note that in the above description, the semiconductor layer provided between the substrate 10 and the light-emitting layer 24 is the p-type semiconductor layer, and the semiconductor layer provided on a side of the light-emitting layer 24 opposite to the substrate 10 is the n-type semiconductor layer, but the p-type and the n-type may be reversed. That is, a semiconductor layer provided between the substrate 10 and the light-emitting layer 24 may be an n-type semiconductor layer, and a semiconductor layer provided on the side of the light-emitting layer 24 opposite to the substrate 10 may be a p-type semiconductor layer. In this case, the electrode electrically coupled to the semiconductor layer provided between the substrate 10 and the light-emitting layer 24 is the n-electrode, and the electrode electrically coupled to the semiconductor layer provided on the side of the light-emitting layer 24 opposite to the substrate 10 is the p-electrode.

Additionally, although the example in which there is an air gap between the substrate 10 and the protective layer 60 has been described above, the substrate 10 and the protective layer 60 may be in contact with each other. In this case, the pad 12 may be embedded in the substrate 10. The pad 12 and the light-emitting element 2 may be coupled to each other by hybrid bonding.

Additionally, although the example in which the lower metal layer 50 is provided at the first contact hole 48 has been described above, the pad 12 instead of the lower metal layer 50 may be provided at the first contact hole 48 as long as the pad 12 is electrically coupled to the p-electrode 30.

Although the InGaN-based light-emitting layer 24 is described above, the light-emitting layer 24 can be made of various materials that can emit light when a current is injected thereinto, depending on a wavelength of emitted light. For example, semiconductor materials such as an AlGaN based, AlGaAs based, InGaAs based, InGaAsP based, InP based, GaP based, and AlGaP based materials can be used.

### 2. Method of Manufacturing Light-Emitting Device

Next, a method of manufacturing the light-emitting device 100 according to the present embodiment will be described with reference to the drawings. FIGS. 3 to 10 are each a cross-sectional view schematically illustrating a manufacturing step of the light-emitting device 100 according to the present embodiment.

As illustrated in FIG. 3, the n-type semiconductor layer 26, the light-emitting layer 24, and the p-type semiconductor layer 22 are epitaxially grown at a growth substrate 17 in this order. Examples of the epitaxial growth method include a metal organic chemical vapor deposition (MOCVD) method and a molecular beam epitaxy (MBE) method. Through this step, the stacked body 20 is formed. The growth substrate 17 is a substrate for epitaxially growing the stacked body 20. The growth substrate 17 includes, for example, a support substrate 18 and a buffer layer 19 provided at the support substrate 18. The support substrate 18 is, for example, a silicon substrate. The buffer layer 19 is, for example, a GaN layer.

Next, the p-electrode 30 is formed at the stacked body 20. The p-electrode 30 is formed by, for example, a vacuum deposition method, a sputtering method, or a chemical vapor deposition (CVD) method.

Next, the p-electrode 30 and the stacked body 20 are patterned. The patterning is performed such that the side surface 21 of the tapered portion 20a of the stacked body 20 is inclined with respect to the stacking direction. The patterning is performed by, for example, photolithography and dry etching. By collectively patterning the p-electrode 30 and the stacked body 20, the manufacturing step of the light-emitting device 100 can be shortened.

Next, the insulating layer 40 is formed at the stacked body 20 and the buffer layer 19. The insulating layer 40 is formed by, for example, a CVD method or an ALD method.

Next, the insulating layer 40 is patterned to form the first contact hole 48. Thus, the p-electrode 30 is exposed. The patterning is performed by, for example, photolithography and etching.

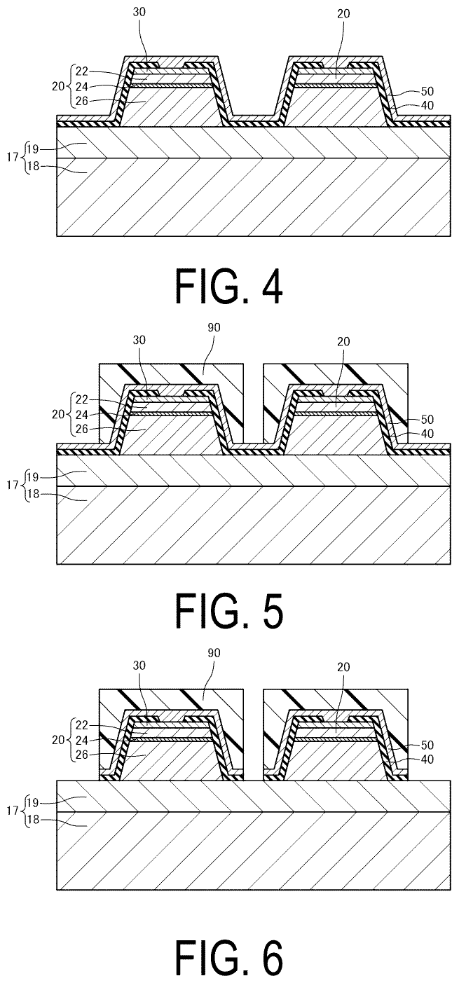

As illustrated in FIG. 4, the lower metal layer 50 is formed at the p-electrode 30 and at the insulating layer 40. The lower metal layer 50 is formed by, for example, a vacuum deposition method or a sputtering method.

As illustrated in FIG. 5, a resist layer 90 having a predetermined shape is formed so as to cover the stacked body 20. The resist layer 90 is formed by coating, exposing, and developing.

As illustrated in FIG. 6, the lower metal layer 50 and the insulating layer 40 are dry-etched using the resist layer 90 as a mask. In this manner, the buffer layer 19 is exposed. Here, the insulating layer 40 need not be completely dry-etched for exposing the buffer layer 19.

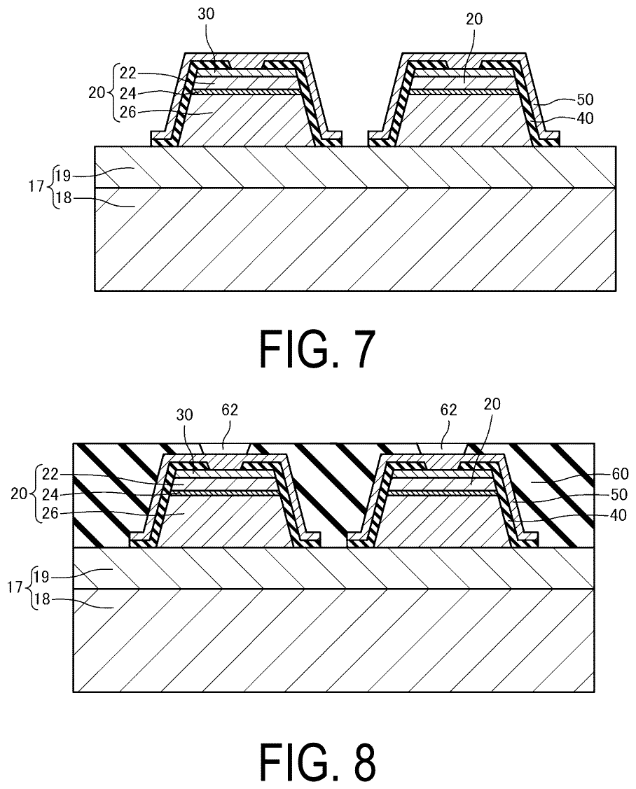

The resist layer 90 is removed as illustrated in FIG. 7. A method of removing the resist layer 90 is not particularly limited.

As illustrated in FIG. 8, the protective layer 60 is formed so as to cover the stacked body 20. The protective layer 60 is formed by, for example, a CVD method or a spin coating method, and the protective layer 60 is planarized using a CMP (Chemical Mechanical Polishing) apparatus or the like.

Next, the protective layer 60 is patterned to form the second contact hole 62. Thus, the lower metal layer 50 is exposed. The patterning is performed by, for example, photolithography and etching.

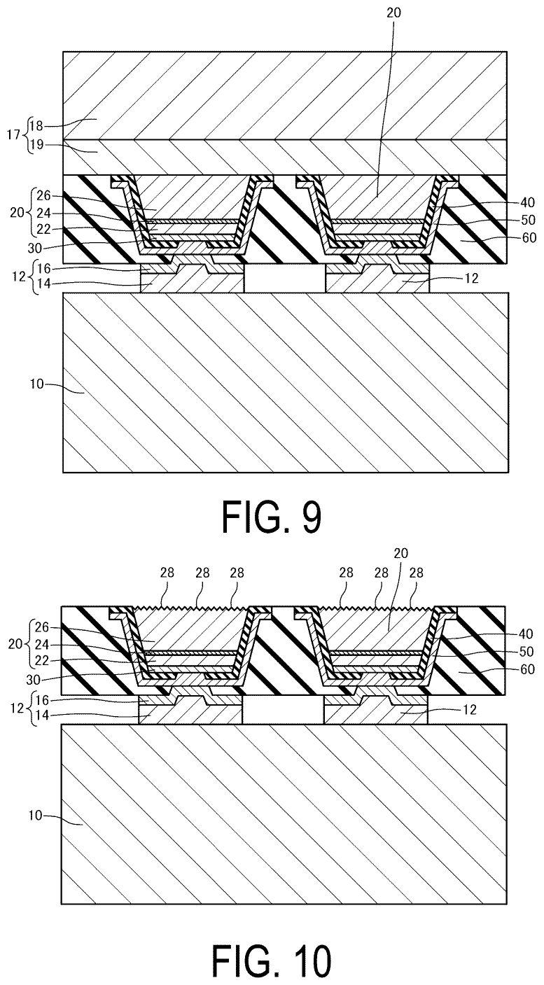

As illustrated in FIG. 9, the lower metal layer 50 is bonded to the pad 12. Examples of the bonding include eutectic bonding and Au—Au bonding. Note that both may be bonded to each other using solder or the like.

As illustrated in FIG. 10, the growth substrate 17 is removed. The removal of the growth substrate 17 is performed by, for example, etching, CMP, or the like. Thus, the n-type semiconductor layer 26 is exposed.

Next, the n-type semiconductor layer 26 is patterned to form the plurality of protrusions 28. The patterning is performed by, for example, photolithography and etching.

As illustrated in FIG. 1, the n-electrode 32 is formed at the n-type semiconductor layer 26. The n-electrode 32 is formed by, for example, a vacuum deposition method or a sputtering method.

Next, the upper metal layer 70 is formed above the n-electrode 32 via the adhesion layer 72. The upper metal layer 70 and the adhesion layer 72 are formed by, for example, a sputtering method, a CVD method, a vacuum deposition method, or a plating method.

Next, the light-transmissive member 80 is formed at the n-electrode 32. The light-transmissive member 80 is formed by, for example, a CVD method.

Next, the light-transmissive member 80 is patterned to form the emission surface 82 which is a curved surface. The patterning is performed by, for example, photolithography and etching.

The light-emitting device 100 can be manufactured through the above-described steps.

### 3. Projector

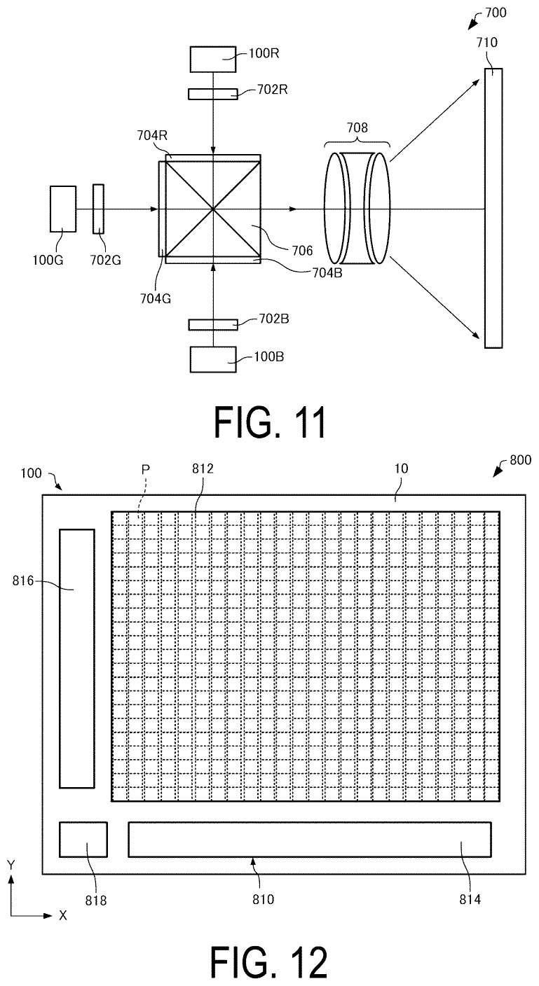

Next, a projector as an electronic apparatus according to the present embodiment is described with reference to the drawings. FIG. 11 is a diagram schematically illustrating a projector 700 according to the present embodiment.

The projector 700 includes, for example, the light-emitting device 100 as a light source.

The projector 700 includes a housing, which is not illustrated in the drawing, and a red light source 100R, a green light source 100G, and a blue light source 100B that are provided in the housing and emit red light, green light, and blue light, respectively. Note that for the sake of convenience, the red light source 100R, the green light source 100G, and the blue light source 100B illustrated in FIG. 11 are simplified.

The projector 700 further includes, for example, a first optical element 702R, a second optical element 702G, a third optical element 702B, a first optical modulation device 704R, a second optical modulation device 704G, a third optical modulation device 704B, and a projection device 708 which are provided in the housing. The first optical modulation device 704R, the second optical modulation device 704G, and the third optical modulation device 704B are, for example, transmissive liquid crystal light valves. The projection device 708 is, for example, a projection lens.

The light emitted from the red light source 100R is incident on the first optical element 702R. The light emitted from the red light source 100R is condensed by the first optical element 702R. Note that the first optical element 702R may have a function other than that of condensing light. The second optical element 702G and the third optical element 702B may also have a function other than that of condensing light.

The light condensed by the first optical element 702R is incident on the first optical modulation device 704R. The first optical modulation device 704R modulates the incident light based on image information. Then, the projection device 708 enlarges an image formed by the first optical modulation device 704R and projects the image on a screen 710.

The light emitted from the green light source 100G is incident on the second optical element 702G. The light emitted from the green light source 100G is condensed by the second optical element 702G.

The light condensed by the second optical element 702G is incident on the second optical modulation device 704G. The second optical modulation device 704G modulates the incident light based on image information. Then, the projection device 708 enlarges an image formed by the second optical modulation device 704G and projects the image on the screen 710.

The light emitted from the blue light source 100B is incident on the third optical element 702B. The light emitted from the blue light source 100B is condensed by the third optical element 702B.

The light condensed by the third optical element 702B is incident on the third optical modulation device 704B. The third optical modulation device 704B modulates the incident light based on image information. Then, the projection device 708 enlarges the image formed by the third optical modulation device 704B and projects the image on the screen 710.

The projector 700 further includes, for example, a cross dichroic prism 706 that synthesizes the light emitted from the first optical modulation device 704R, the light emitted from the second optical modulation device 704G, and the light emitted from the third optical modulation device 704B and guides the synthesized light to the projection device 708.

Light beams of three colors modulated by the first optical modulation device 704R, the second optical modulation device 704G, and the third optical modulation device 704B are incident on the cross dichroic prism 706. In the cross dichroic prism 706, four right-angle prisms are bonded together, and a dielectric multilayer film that reflects red light and a dielectric multilayer film that reflects blue light are disposed on inner surfaces of the prisms. The light beams of three colors are synthesized by the dielectric multilayer films, and light representing a color image is formed. Then, the synthesized light is projected onto the screen 710 by the projection device 708, and an enlarged image is displayed.

The red light source 100R, the green light source 100G, and the blue light source 100B control the light-emitting devices 100 as pixels of a video based on image information, and thus the video may be directly formed without using the first optical modulation device 704R, the second optical modulation device 704G, and the third optical modulation device 704B. The projection device 708 may project the video formed by the red light source 100R, the green light source 100G, and the blue light source 100B onto the screen 710 in an enlarged manner.

Although the transmissive liquid crystal light valve is used as the optical modulation device in the above-described example, a light valve other than the liquid crystal light valve may be used, or a reflective light valve may be used. Examples of such a light valve include a reflective liquid crystal light valve and a digital micro mirror device. A configuration of the projection device is changed as appropriate depending on the type of light valve to be used.

The light source can also be applied to a light source device of a scanning type image display device including a scanning unit which is an image forming device for displaying an image having a desired size on a display surface by scanning a screen with light emitted from the light source.

### 4. Display

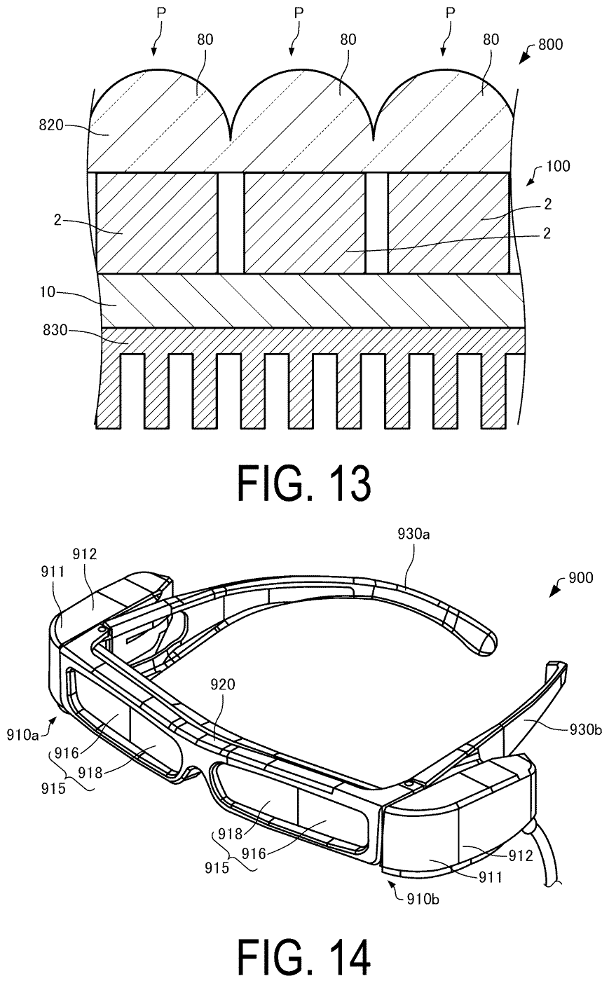

Next, a display as an electronic apparatus according to the present embodiment will be described with reference to the drawings. FIG. 12 is a plan view schematically illustrating a display 800 according to the present embodiment. FIG. 13 is a cross-sectional view schematically illustrating the display 800 according to the present embodiment. Note that an X-axis and a Y-axis are illustrated in FIG. 12 as two axes orthogonal to each other. Further, for the sake of convenience, the light-emitting device 100 is illustrated in FIGS. 12 and 13 in a simplified manner.

The display 800 includes, for example, the light-emitting device 100 as a light source.

The display 800 is a display device that displays an image. The image includes those only displaying character information. The display 800 is a self-luminous display. As illustrated in FIGS. 12 and 13, the display 800 includes, for example, a driving circuit 810, a lens array 820, and a heat sink 830.

The driving circuit 80 is provided at the substrate 10. The driving circuit 810 drives the light-emitting element 2 based on, for example, input image information. The substrate 10 includes, for example, a display region 812. The driving circuit 810 includes a data line driving circuit 814, a scanning line driving circuit 816, and a control circuit 818.

The display region 812 is constituted by a plurality of pixels P. In the example illustrated in the drawing, the pixels P are arrayed along the X-axis and the Y-axis.

Although not illustrated in the drawing, the substrate 10 is provided with a plurality of scanning lines and a plurality of data lines. For example, the scanning lines extend along the X-axis and the data lines extend along the Y-axis. The scanning lines are coupled to the scanning line driving circuit 816. The data lines are coupled to the data line driving circuit 814. The pixels P are provided corresponding to intersections between the scanning lines and the data lines.

One pixel P includes, for example, one light-emitting element 2, one light-transmissive member 80, and a pixel circuit (not illustrated). The pixel circuit includes a switching transistor that serves as a switch for the pixel P, a gate of the switching transistor is coupled to the scanning line, and one of a source and a drain thereof is coupled to the data line.

The data line driving circuit 814 and the scanning line driving circuit 816 are circuits that control driving of the light-emitting element 2 constituting the pixel P. The control circuit 818 controls display of an image.

Image data is supplied to the control circuit 818 from an upper level circuit. The control circuit 818 supplies various signals based on the image data to the data line driving circuit 814 and the scanning line driving circuit 816.

When the scanning line is selected by activating a scanning signal by the scanning line driving circuit 816, the switching transistor of the selected pixel P is turned on. At this time, the data line driving circuit 814 supplies a data signal from the data line to the selected pixel P, and thus the light-emitting element 2 of the selected pixel P emits light based on the data signal.

The lens array 820 is constituted by a plurality of the light-transmissive members 80. The heat sink 830 is in contact with the substrate 10. A material of the heat sink 830 is, for example, metal such as copper or aluminum. The heat sink 830 radiates heat generated by the light-emitting element 2.

### 5. Head-Mounted Display

### 5.1. Overall Configuration

Next, a head-mounted display as an electronic apparatus according to the present embodiment will be described with reference to the drawings. FIG. 14 is a perspective view schematically illustrating a head-mounted display 900 according to the present embodiment.

As illustrated in FIG. 14, the head-mounted display 900 is a head-mounted display that has an outer appearance of an eyewear. The head-mounted display 900 is mounted on a head of a viewer. The viewer is a user who uses the head-mounted display 900. The head-mounted display 900 allows the viewer to visually recognize video light of a virtual image and to visually recognize an external image in a see-through manner.

The head-mounted display 900 includes, for example, a first display unit 910a, a second display unit 910b, a frame 920, a first temple 930a, and a second temple 930b.

The first display unit 910a and the second display unit 910b display images. Specifically, the first display unit 910a displays a virtual image for a right eye of the viewer. The second display unit 910b displays a virtual image for a left eye of the viewer. The display units 910a and 910b each include, for example, an image forming device 911 and a light-guiding device 915.

The image forming device 911 generates image light. The image forming device 911 includes, for example, an optical system such as a light source and a projection device, and an external member 912. The external member 912 accommodates the light source and the projection device.

The light-guiding device 915 covers a front of the eyes of the viewer. The light-guiding device 915 guides the video light formed by the image forming device 911 and allows the viewer to visually recognize external light and the video light in an overlapping manner. Details of the image forming device 911 and the light-guiding device 915 will be described below.

The frame 920 supports the first display unit 910a and the second display unit 910b. For example, the frame 920 surrounds the display units 910a and 910b. In the example illustrated in the drawing, the image forming device 911 of the first display unit 910a is attached to one end portion of the frame 920. The image forming device 911 of the second display unit 910b is attached to another end portion of the frame 920.

The first temple 930a and the second temple 930b extend from the frame 920. In the example illustrated in the drawing, the first temple 930a extends from the one end portion of the frame 920. The second temple 930b extends from the other end portion of the frame 920.

The first temple 930a and the second temple 930b are put on ears of the viewer when the head-mounted display 900 is worn by the viewer. The head of the viewer is positioned between the temples 930a and 930b.

### 5.2. Image Forming Device and Light-Guiding Device

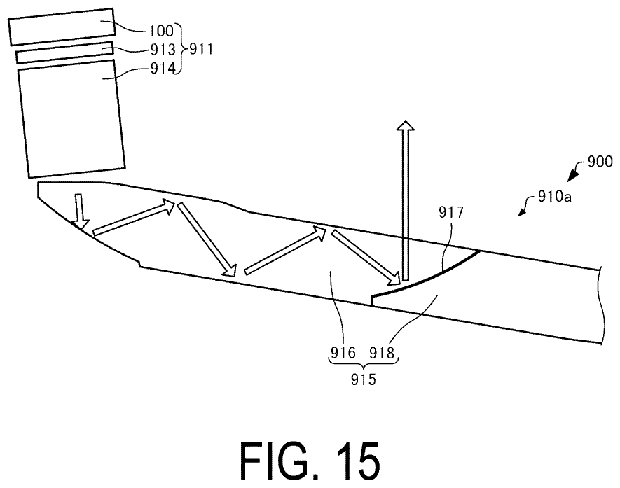

FIG. 15 is a diagram schematically illustrating the image forming device 911 and the light-guiding device 915 of the first display unit 910a of the head-mounted display 900. The first display unit 910a and the second display unit 910b have basically the same configuration. Thus, the following description of the first display unit 910a can be applied to the second display unit 910b.

As illustrated in FIG. 15, the image forming device 911 includes, for example, the light-emitting device 100 as a light source, an optical modulation device 913, and a projection device 914 for image formation.

The optical modulation device 913 modulates light incident from the light-emitting device 100 based on image information, and emits video light. The optical modulation device 913 is a transmissive liquid crystal light valve. The light-emitting device 100 may be a self-luminous light-emitting device that emits light based on the image information input. In this case, the optical modulation device 913 is not provided.

The projection device 914 projects the video light emitted from the optical modulation device 913 toward the light-guiding device 915. The projection device 914 is, for example, a projection lens. As the lens constituting the projection device 914, a lens having an axially symmetric surface as a lens surface may be used.

The light-guiding device 915 is accurately positioned with respect to the projection device 914, for example, by being screwed to a lens barrel of the projection device 914. The light-guiding device 915 includes, for example, a video light-guiding member 916 that guides the video light and a see-through member 918 for see-through view.

The video light emitted from the projection device 914 is incident on the video light-guiding member 916. The video light-guiding member 916 is a prism that guides the video light toward the eyes of the viewer. The video light incident on the video light-guiding member 916 is repeatedly reflected on an inner surface of the video light-guiding member 916, and is then reflected by a reflective layer 917 to be emitted from the video light-guiding member 916. The video light emitted from the video light-guiding member 916 reaches the eyes of the viewer. The reflective layer 917 is constituted by, for example, a metal or a dielectric multilayer film. The reflective layer 917 may be a half mirror.

The see-through member 918 is adjacent to the video light-guiding member 916. The see-through member 918 is fixed to the video light-guiding member 916. An outer surface of the see-through member 918 is continuous with, for example, an outer surface of the video light-guiding member 916. The viewer sees external light through the see-through member 918. The video light-guiding member 916 also has a function of making the viewer see the external light therethrough, in addition to the function of guiding video light. The head-mounted display 900 may be configured not to allow the viewer to see the external light therethrough.

The light-emitting devices according to the embodiments described above can be used for devices other than the projector, the display, and the head-mounted display. The light-emitting device according to the above-described embodiment is used for, for example, indoor and outdoor lighting, a laser printer, a scanner, a sensing device using light, an electronic view finder (EVF), a wearable display such as a smart watch, an in-vehicle light, and an in-vehicle head-up display.

The embodiment and the modification examples described above are merely examples, and are not intended as limiting. For example, each embodiment and each modification example can also be combined together as appropriate.

The present disclosure includes configurations that are substantially identical to the configurations described in the embodiment, for example, configurations with identical functions, methods and results, or with identical objects and effects. Also, the present disclosure includes configurations obtained by replacing non-essential portions of the configurations described in the embodiment. In addition, the present disclosure includes configurations having the same operations and effects or can achieve the same objects as the configurations described in the embodiment. Further, the present disclosure includes configurations obtained by adding known techniques to the configurations described in the embodiment.

The following contents are derived from the embodiment and the modification examples described above.

A light-emitting device includes
a substrate,
a first stacked body including a first semiconductor layer of a first conductivity type, a second semiconductor layer of a second conductivity type different from the first conductivity type, and a first light-emitting layer provided between the first semiconductor layer and the second semiconductor layer,
a first electrode provided between the substrate and the first stacked body, and electrically coupled to the first semiconductor layer,
a second electrode provided on a side of the first stacked body opposite to the substrate, having a light-transmitting property, including a first facing surface facing the substrate, and electrically coupled to the second semiconductor layer,
a first insulating layer including a first portion provided at a side surface of the first stacked body, and a second portion provided at the first facing surface, and extending from the first portion along the first facing surface, and
a first metal layer provided over the first portion and the second portion.

According to this light-emitting device, light extraction efficiency can be improved.

In an aspect of the light-emitting device,
the first metal layer may be coupled to the first electrode.

According to this light-emitting device, it is possible to achieve miniaturization.

In an aspect of the light-emitting device,
a second stacked body including a third semiconductor layer of the first conductivity type, a fourth semiconductor layer of the second conductivity type, and a second light-emitting layer provided between the third semiconductor layer and the fourth semiconductor layer,
a third electrode provided between the substrate and the second stacked body, and electrically coupled to the third semiconductor layer,
a fourth electrode provided on a side of the second stacked body opposite to the substrate, having a light-transmitting property, including a second facing surface facing the substrate, and electrically coupled to the fourth semiconductor layer,
a second insulating layer including a third portion provided at a side surface of the second stacked body, and a fourth portion provided at the second facing surface, and extending from the third portion along the second facing surface, and
a second metal layer provided over the third portion and the fourth portion
may be included.

According to this light-emitting device, it is possible to reduce crosstalk between a first light-emitting element including the first stacked body, the first electrode, and a second electrode, and a second light-emitting element including the second stacked body, the third electrode, and the fourth electrode.

In an aspect of the light-emitting device,
the second electrode and the fourth electrode may be continuously and integrally provided.

According to this light-emitting device, the second electrode and the fourth electrode can be used as a common electrode in the first light-emitting element and the second light-emitting element.

In an aspect of the light-emitting device,
the first stacked body may include a tapered portion having a width that increases as viewed from the first electrode side toward the second electrode side.

According to this light-emitting device, light generated in the first light-emitting layer can be reflected toward the second electrode side at the side surface of the stacked body.

In an aspect of the light-emitting device,
a third metal layer provided on a side of the second electrode opposite to the substrate, and including a reflective surface for reflecting the light generated in the first light-emitting layer may be included, and
the reflective surface may be located on an extension of a side surface of the tapered portion.

According to this light-emitting device, it is possible to emit light having a narrower radiation angle while suppressing leakage of light transmitted through the second electrode to an outside.

In an aspect of the light-emitting device,
a light-transmissive member provided on a side of the second electrode opposite to the substrate, and in contact with the reflective surface may be included.

According to this light-emitting device, light transmitted through the light-transmissive member and incident on the reflective surface can be more reliably reflected toward the light-transmissive member side at the reflective surface.

In an aspect of the light-emitting device,
a surface of the light-transmissive member opposite to the substrate may be a curved surface.

According to this light-emitting device, the light-transmissive member can function as a lens.

In an aspect of the light-emitting device,
the first insulating layer may have a light-transmitting property.

According to this light-emitting device, even when the light generated in the first light-emitting layer is transmitted through the light-transmissive first insulating layer, light transmitted through the first insulating layer can be reflected by the first metal layer toward the first stacked body side.

An aspect of an electronic apparatus
includes an aspect of the light-emitting device.

What is claimed is:

1. A light-emitting device, comprising:
a substrate;
a first stacked body including a first semiconductor layer of a first conductivity type, a second semiconductor layer of a second conductivity type different from the first conductivity type, and a first light-emitting layer provided between the first semiconductor layer and the second semiconductor layer;
a first electrode provided between the substrate and the first stacked body, and electrically coupled to the first semiconductor layer;
a second electrode provided on a side of the first stacked body opposite to the substrate, having a light-transmitting property, including a first facing surface facing the substrate, and electrically coupled to the second semiconductor layer;
a first insulating layer including a first portion provided at a side surface of the first stacked body, and a second portion provided at the first facing surface, and extending from the first portion along the first facing surface; and
a first metal layer provided over the first portion and the second portion.

2. The light-emitting device according to claim 1, wherein the first metal layer is coupled to the first electrode.

3. The light-emitting device according to claim 1, comprising:
a second stacked body including a third semiconductor layer of the first conductivity type, a fourth semiconductor layer of the second conductivity type, and a second light-emitting layer provided between the third semiconductor layer and the fourth semiconductor layer;
a third electrode provided between the substrate and the second stacked body, and electrically coupled to the third semiconductor layer;
a fourth electrode provided on a side of the second stacked body opposite to the substrate, having a light-transmitting property, including a second facing surface facing the substrate, and electrically coupled to the fourth semiconductor layer;
a second insulating layer including a third portion provided at a side surface of the second stacked body, and a fourth portion provided at the second facing surface, and extending from the third portion along the second facing surface; and
a second metal layer provided over the third portion and the fourth portion.

4. The light-emitting device according to claim 3, wherein
the second electrode and the fourth electrode are continuously and integrally provided.

5. The light-emitting device according to claim 1, wherein
the first stacked body includes a tapered portion having a width that increases as viewed from the first electrode side toward the second electrode side.

6. The light-emitting device according to claim 5, comprising a third metal layer provided on a side of the second electrode opposite to the substrate, and including a reflective surface for reflecting light generated in the first light-emitting layer, and
the reflective surface is located on an extension of a side surface of the tapered portion.

7. The light-emitting device according to claim 6, comprising a light-transmissive member provided on the side of the second electrode opposite to the substrate and in contact with the reflective surface.

8. The light-emitting device according to claim 7, wherein
a surface of the light-transmissive member opposite to the substrate is a curved surface.

9. The light-emitting device according to claim 1, wherein
the first insulating layer has a light-transmitting property.

10. An electronic apparatus comprising the light-emitting device according to claim 1.
